(19) United States
(12) Patent Application Publication
(10) Pub. No.: US 2011/0094586 A1
(43) Pub. Date: Apr. 28, 2011

(54) SOLAR CELL AND METHOD FOR MANUFACTURING THE SAME

(76) Inventors: Juhwa CHEONG, Seoul (KR); Junyong Ahn, Seoul (KR); Youngsung Yang, Seoul (KR); Seongeun Lee, Seoul (KR)

(21) Appl. No.: 12/913,259

(22) Filed: Oct. 27, 2010

(30) Foreign Application Priority Data
Oct. 28, 2009 (KR) 10-2009-0102760

(51) Int. Cl. H01L 31/0232

(52) U.S. Cl. 136/259; 438/72; 257/E31.127

(57) ABSTRACT

A solar cell and a method for manufacturing the same are discussed. The solar cell includes a substrate of a first conductive type, an emitter portion that has a second conductive type opposite the first conductive type and forms a p-n junction along with the substrate, a first anti-reflection layer that is positioned on the emitter portion and has a thickness of about 5 nm to 35 nm, a second anti-reflection layer positioned on the first anti-reflection layer, a first electrode electrically connected to the emitter portion, and a second electrode electrically connected to the substrate.

This application claims priority to and the benefit of Korean Patent Application No. 10-2009-0102760 filed in the Korean Intellectual Property Office on Oct. 28, 2009, the entire contents of which are incorporated herein by reference.

### BACKGROUND OF THE INVENTION

1. Field of the Invention

Embodiments of the invention relate to a solar cell and a method for manufacturing the same.

2. Description of the Related Art

Recently, as existing energy sources such as petroleum and coal are expected to be depleted, interests in alternative energy sources for replacing the existing energy sources are increasing. Among the alternative energy sources, solar cells for generating electric energy from solar energy have been particularly spotlighted.

A solar cell generally includes semiconductor parts that have different conductive types, such as a p-type and an n-type, and form a p-n junction, and electrodes respectively connected to the semiconductor parts of the different conductive types.

When light is incident on the solar cell, a plurality of electron-hole pairs are generated in the semiconductor parts. The electron-hole pairs are separated into electrons and holes by the photovoltaic effect. Thus, the separated electrons move to the n-type semiconductor and the separated holes move to the p-type semiconductor, and then the electrons and holes are collected by the electrodes electrically connected to the n-type semiconductor and the p-type semiconductor, respectively. The electrodes are connected to each other using electric wires to thereby obtain electric power.

### SUMMARY OF THE INVENTION

In one aspect, there is a solar cell including a substrate of a first conductive type, an emitter portion of a second conductive type opposite the first conductive type, the emitter portion forming a p-n junction along with the substrate, a first anti-reflection layer positioned on the emitter portion, the first anti-reflection layer having a thickness of about 5 nm to 35 nm, a second anti-reflection layer positioned on the first anti-reflection layer, a first electrode electrically connected to the emitter portion, and a second electrode electrically connected to the substrate.

The first anti-reflection layer may be formed of silicon oxynitride. The first anti-reflection layer may have a refractive index of about 1.5 to 3.4.

The second anti-reflection layer may be formed of silicon nitride. The second anti-reflection layer may have a thickness of about 50 nm to 100 nm and a refractive index of about 1.45 to 2.4.

The solar cell may further include a back surface field layer positioned between the substrate and the second electrode.

In another aspect, there is a method for manufacturing a solar cell including forming an emitter portion of a second conductive type opposite a first conductive type at a substrate of the first conductive type, forming a first anti-reflection layer on the emitter portion to a thickness of about 5 nm to 35 nm, forming a second anti-reflection layer on the first anti-reflection layer, and forming a first electrode electrically connected to the emitter portion and a second electrode electrically connected to the substrate.

The forming of the first anti-reflection layer may include forming the first anti-reflection layer using silicon oxynitride. The first anti-reflection layer may have a refractive index of about 1.5 to 3.4.

The forming of the second anti-reflection layer may include forming the second anti-reflection layer using silicon nitride. The second anti-reflection layer may have a thickness of about 50 nm to 100 nm and a refractive index of about 1.45 to 2.4.

The forming of the first and second electrodes may include printing a first paste on the second anti-reflection layer to form a first electrode pattern, printing a second paste on the substrate to form a second electrode pattern, and performing a thermal process on the substrate having the first electrode pattern and second electrode pattern to respectively form the first electrode electrically connected to the emitter portion and the second electrode electrically connected to the substrate.

The forming of the first and second electrodes may further include forming a back surface field layer between the substrate and the second electrode when the thermal process is performed on the substrate.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 is a partial perspective view of a solar cell according to an example embodiment of the invention;

FIG. 2 is a cross-sectional view taken along line II-II of FIG. 1;

FIGS. 3A to 3E are cross-sectional views sequentially illustrating a method for manufacturing a solar cell according to an example embodiment of the invention; and

FIG. 4 is a graph indicating an internal quantum efficiency (IQE) value depending on a wavelength in example of a solar cell according to an example embodiment of the invention and an example of a solar cell according to the related art.

### DETAILED DESCRIPTION OF THE EMBODIMENTS

The invention will be described more fully hereinafter with reference to the accompanying drawings, in which example embodiments of the inventions are shown. This invention may, however, be embodied in many different forms and should not be construed as limited to the embodiments set forth herein.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, it will be understood that when an element such as a layer, film, region, or substrate is referred to as being “entirely” on another element, it may be on the entire surface of the other element and may not be on a portion of an edge of the other element.

Reference will now be made in detail to embodiments of the invention, examples of which are illustrated in the accompanying drawings.

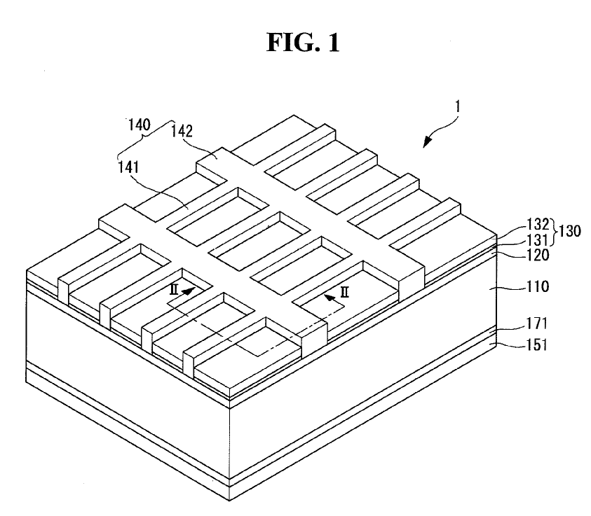

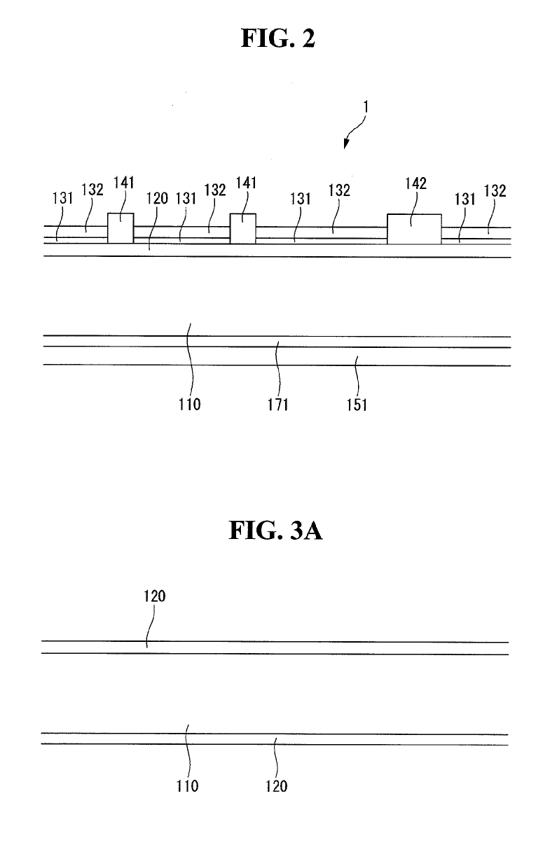

FIG. 1 is a partial perspective view of a solar cell according to an example embodiment of the invention. FIG. 2 is a cross-sectional view taken along line II-II of FIG. 1.

As shown in FIGS. 1 and 2, a solar cell 1 according to an example embodiment of the invention includes a substrate 110, an emitter portion 120 positioned at the substrate 110, an anti-reflection layer 130 on the emitter portion 120 positioned at a surface (hereinafter, referred to as “a front surface”) of the substrate 110 on which light is incident, a front electrode part 140 positioned on the emitter portion 120 of the front surface of the substrate 110, a back electrode 151 positioned on a surface (hereinafter, referred to as “a back surface”), opposite the front surface of the substrate 110, on which light is not incident, and a back surface field layer 171 positioned between the substrate 110 and the back electrode 151.

The substrate 110 is a semiconductor substrate formed of first conductive type silicon, for example, p-type silicon, though not required. Silicon used in the substrate 110 may be crystalline silicon such as single crystal silicon and polycrystalline silicon or amorphous silicon. When the substrate 110 is of a p-type, the substrate 110 may contain impurities of a group III element such as boron (B), gallium (Ga), and indium (In).

Alternatively, the substrate 110 may be of an n-type. When the substrate 110 is of the n-type, the substrate 110 may contain impurities of a group V element such as phosphor (P), arsenic (As), and antimony (Sb). Further, the substrate 110 may be formed of semiconductor materials other than silicon.

The surface of the substrate 110 may be textured to form a textured surface corresponding to an uneven surface or having uneven characteristics. In this instance, an amount of light incident on the substrate 110 increases because of the textured surface of the substrate 110, and thus the efficiency of the solar cell 1 is improved.

The emitter portion 120 formed at the substrate 110 is an impurity region of a second conductive type (for example, an n-type) opposite the first conductive type (for example, a p-type) of the substrate 110, and thus forms a p-n junction along with the substrate 110.

A plurality of electron-hole pairs produced by light incident on the substrate 110 are separated into electrons and holes by a built-in potential difference resulting from the p-n junction between the substrate 110 and the emitter portion 120. Then, the separated electrons move to the n-type semiconductor, and the separated holes move to the p-type semiconductor. Thus, when the substrate 110 is of the p-type and the emitter portion 120 is of the n-type, the separated holes and the separated electrons move to the substrate 110 and the emitter portion 120, respectively.

Because the substrate 110 and the emitter portion 120 form the p-n junction, the emitter portion 120 may be of the p-type when the substrate 110 is of the n-type unlike the embodiment described above. In this instance, the separated electrons and the separated holes move to the substrate 110 and the emitter portion 120, respectively.

Returning to the embodiment of the invention, when the emitter portion 120 is of the n-type, the emitter portion 120 may be formed by doping the substrate 110 with impurities of a group V element such as P, As, and Sb. On the contrary, when the emitter portion 120 is of the p-type, the emitter portion 120 may be formed by doping the substrate 110 with impurities of a group III element such as B, Ga, and In.

The anti-reflection layer 130 includes a first anti-reflection layer 131 positioned on the emitter portion 120 and a second anti-reflection layer 132 positioned on the first anti-reflection layer 131.

The first anti-reflection layer 131 is formed of silicon oxynitride (SiOxNy) and has a thickness of about 5 nm to 35 nm and a refractive index of about 1.5 to 3.4.

The first anti-reflection layer 131 implements a passivation effect that converts a defect, for example, dangling bonds existing at the surface of the substrate 110 into stable bonds to thereby prevent or reduce a recombination and/or a disappearance of carriers moving to the substrate 110 resulting from the defect. Further, the first anti-reflection layer 131 reduces a reflectance of light incident on the substrate 110.

When the refractive index of the first anti-reflection layer 131 is less than about 1.5, an anti-reflection operation of the first anti-reflection layer 131 is not well performed because of a smooth reflection of light. Hence, the passivation effect of the first anti-reflection layer 131 is reduced, and the efficiency of the solar cell 1 is reduced. When the refractive index of the first anti-reflection layer 131 is greater than about 3.4, the photoelectric efficiency of the substrate 110 is reduced because incident light is absorbed in the first anti-reflection layer 131. Further, it is difficult to form a layer, with a refractive index that is outside of the refractive index range of about 1.5 to 3.4, using silicon oxynitride (SiOxNy) because of the properties of SiOxNy.

When the thickness of the first anti-reflection layer 131 is less than about 5 nm, the anti-reflection operation of the first anti-reflection layer 131 is not well performed. When the thickness of the first anti-reflection layer 131 is greater than about 35 nm, the manufacturing cost and process time increase because of an unnecessary increase in the thickness of the first anti-reflection layer 131.

The second anti-reflection layer 132 is positioned only on the first anti-reflection layer 131. The second anti-reflection layer 132 is formed of silicon nitride (SiNx) and has a thickness of about 50 nm to 100 nm and a refractive index of about 1.45 to 2.4.

The second anti-reflection layer 132 reduces a reflectance of light incident on the substrate 110 and further increases an amount of light absorbed in the substrate 110 along with the first anti-reflection layer 131. Further, the second anti-reflection layer 132 further improves the passivation effect due to hydrogen (H) of silicon nitride (SiNx) forming the second anti-reflection layer 132.

As described above, the refractive index of the second anti-reflection layer 132 is less than (or in a lower range than) the refractive index of the first anti-reflection layer 131. A change of the refractive index from the first anti-reflection layer 131 to the second anti-reflection layer 132 nonsuccessively decreases.

When the refractive index of the second anti-reflection layer 132 is less than about 1.45, an anti-reflection operation of the second anti-reflection layer 132 is not well performed because of a smooth reflection of light. When the refractive index of the second anti-reflection layer 132 is greater than about 2.4, the photoelectric efficiency of the substrate 110 is reduced because incident light is absorbed in the second anti-reflection layer 132.

When the thickness of the second anti-reflection layer 132 is less than about 50 nm, the anti-reflection operation of the second anti-reflection layer 132 is not well performed. When the thickness of the second anti-reflection layer 132 is greater than about 100 nm, light is absorbed in the second anti-reflection layer 132.

As shown in FIGS. 1 and 2, the front electrode part 140 includes a plurality of front electrodes 141 and a plurality of front electrode current collectors 142.

The plurality of front electrodes 141 are electrically and physically connected to the emitter portion 120 and extend substantially parallel to one another in a fixed direction. The front electrodes 141 collect carriers (e.g., electrons) moving to the emitter portion 120.

The plurality of front electrode current collectors 142 are positioned on the emitter portion 120 and extend substantially parallel to one another in a direction crossing an extending direction of the front electrodes 141. The front electrode current collectors 142 are electrically and physically connected to the emitter portion 120 and the front electrodes 141.

The front electrodes 141 and the front electrode current collectors 142 are placed on the same level layer (or coplanar). The front electrode current collector 142 is electrically and physically connected to the corresponding front electrode 141 at crossings of the front electrodes 141 and the front electrode current collectors 142.

Because the front electrode current collectors 142 are connected to the front electrodes 141, the front electrode current collectors 142 collect carriers transferred through the front electrodes 141 and output the carriers to an external device.

The front electrode part 140 contains a conductive material such as silver (Ag). Alternatively, the front electrode part 140 may contain at least one selected from the group consisting of nickel (Ni), copper (Cu), aluminum (Al), tin (Sn), zinc (Zn), indium (In), titanium (Ti), gold (Au), and a combination thereof. Other conductive materials may be used.

The first anti-reflection layer 131 of the anti-reflection layer 130 is positioned on the emitter portion 120, on which the front electrode part 140 is not positioned, because of the front electrode part 140 electrically and physically connected to the emitter portion 120.

The back electrode 151 is positioned on almost the entire back surface of the substrate 110. The back electrode 151 collects carriers (e.g., holes) moving to the substrate 110.

The back electrode 151 contains at least one conductive material such as Al. Alternatively, the back electrode 151 may contain at least one selected from the group consisting of Ni, Cu, Ag, Sn, Zn, In, Ti, Au, and a combination thereof. Other conductive materials may be used.

The back surface field layer 171 between the back electrode 151 and the substrate 110 is a region (for example, a p⁺-type region) that is more heavily doped with impurities of the same conductive type as the substrate 110 than the substrate 110. The movement of electrons to the back surface of the substrate 110 is prevented or reduced by a potential barrier resulting from a difference between impurity doping concentrations of the substrate 110 and the back surface field layer 171. Thus, a recombination and/or a disappearance of the electrons and the holes around the surface of the substrate 110 are prevented or reduced.

The solar cell 1 having the above-described structure may further include a plurality of back electrode current collectors positioned on the back surface of the substrate 110.

Similar to the front electrode current collectors 142, the back electrode current collectors are electrically connected to the back electrode 151. The back electrode current collectors collect carriers transferred from the back electrode 151 and output the carriers to the external device. The back electrode current collectors contain at least one conductive material such as Al or Ag.

An operation of the solar cell 1 having the above-described structure is described below.

When light irradiated to the solar cell 1 is incident on the substrate 110 through the emitter portion 120, a plurality of electron-hole pairs are generated in the substrate 110 by light energy based on the incident light. In this instance, because a reflection loss of the light incident on the substrate 110 is reduced by the anti-reflection layer 130, an amount of light incident on the substrate 110 further increases.

The electron-hole pairs are separated into electrons and holes by the p-n junction of the substrate 110 and the emitter portion 120, and the separated electrons move to the n-type emitter portion 120 and the separated holes move to the p-type substrate 110. The electrons moving to the n-type emitter portion 120 are collected by the front electrodes 141 and then move to the front electrode current collectors 142. The holes moving to the p-type substrate 110 are collected by the back electrode 151 through the back surface field layer 171. When the front electrode current collectors 142 are connected to the back electrode 151 using electric wires, current flows therein to thereby enable use of the current for electric power.

A loss amount of carriers decreases by the anti-reflection layer 130 including the first anti-reflection layer 131 mainly performing the passivation operation and the second anti-reflection layer 132 mainly performing the anti-reflection operation, and thus an amount of light incident on the solar cell 1 increases. Accordingly, the efficiency of the solar cell 1 is improved.

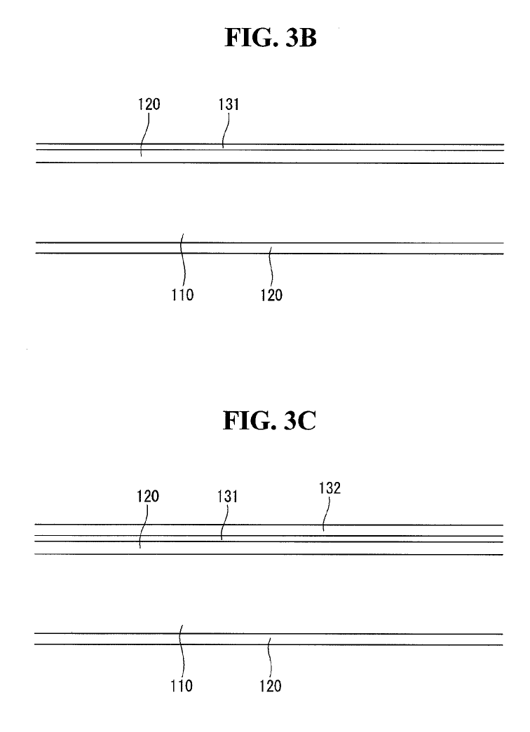

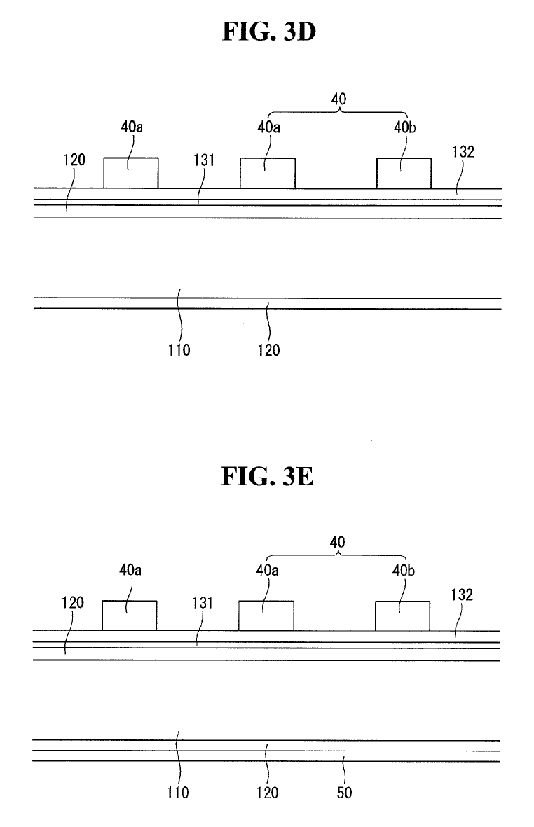

A method for manufacturing the solar cell 1 according to the example embodiment of the invention is described below with reference to FIGS. 3A to 3E.

FIGS. 3A to 3E are cross-sectional views sequentially illustrating a method for manufacturing the solar cell according to the example embodiment of the invention.

First, as shown in FIG. 3A, a high temperature thermal process of a material (for example, POCl₃ or H₃PO₄) containing impurities of a group V element such as P, As, and Sb is performed on the substrate 110 formed of p-type single crystal silicon or p-type polycrystalline silicon to distribute (or dope) the impurities of the group V element in the substrate 110. Hence, the n-type emitter portion 120 is formed at the entire surface of the substrate 110 including a front surface, a back surface, and lateral surfaces of the substrate 110. When the substrate 110 is of an n-type unlike the embodiment of the invention, a high temperature thermal process of a material (for example, B₂H₆) containing impurities of a group III element is performed on the substrate 110 or the material containing the impurities of the group III element is stacked on the substrate 110 to form the p-type emitter portion 120 at the entire surface of the substrate 110.

Subsequently, phosphorous silicate glass (PSG) containing phosphorous (P) or boron silicate glass (BSG) containing boron (B) produced when p-type impurities or n-type impurities are distributed inside the substrate 110 is removed through an etching process.

If necessary, before the emitter portion 120 is formed, a texturing process may be performed on the front surface of the substrate 110 to form a textured surface of the substrate 110. When the substrate 110 is formed of single crystal silicon, the texturing process may be performed using a basic solution such as KOH and NaOH. When the substrate 110 is formed of polycrystalline silicon, the texturing process may be performed using an acid solution such as HF and HNO₃.

Next, as shown in FIG. 3B, a silicon oxynitride (SiOxNy) layer is stacked on the front surface of the substrate 110 in the hydrogen (H) atmosphere using a chemical vapor deposition (CVD) method such as a plasma enhanced CVD method to form the first anti-reflection layer 131. The thickness of the first anti-reflection layer 131 thus formed is approximately 5 nm to 35 nm. Thus, a deposition time required to form the very thin first anti-reflection layer 131 decreases, and the material used decreases. As a result, process time and the manufacturing cost of the solar cell 1 are reduced.

Next, as shown in FIG. 3C, a silicon nitride (SiNx) layer is stacked on the first anti-reflection layer 131 in the hydrogen (H) atmosphere using the CVD method to form the second anti-reflection layer 132.

Next, as shown in FIG. 3D, a front electrode part paste containing silver (Ag) is applied on a desired portion of the second anti-reflection layer 132 using a screen printing method and then is dried at about 170° C. to form a front electrode part pattern 40. The front electrode part pattern 40 includes a front electrode pattern 40a and a current collector pattern 40b.

The front electrode part paste may contain at least one selected from the group consisting of Ni, Cu, Al, Sn, Zn, In, Ti, Au, and a combination thereof, instead of Ag.

Next, as shown in FIG. 3E, a back electrode paste containing aluminum (Al) is applied on a corresponding portion of the back surface of the substrate 110 using the screen printing method and then is dried to form a back electrode pattern 50.

The back electrode paste may contain at least one selected from the group consisting of Ni, Cu, Ag, Sn, Zn, In, Ti, Au, and a combination thereof, instead of Al.

In the embodiment of the invention, a formation order of the front electrode part pattern 40 and the back electrode pattern 50 may vary.

Subsequently, a firing process is performed on the substrate 110 including the front electrode part pattern 40 and the back electrode pattern 50 at a temperature of about 750° C. to 800° C. to form the plurality of front electrodes 141, the plurality of front electrode current collectors 142, the back electrode 151, and the back surface field layer 171.

More specifically, when a thermal process (e.g., a firing process) is performed, the front electrode part pattern 40 sequentially passes through the second anti-reflection layer 132 and the first anti-reflection layer 131 each contacting the front electrode part pattern 40 due to an element such as lead (Pb) contained in the front electrode part pattern 40. Hence, the plurality of front electrodes 141 contacting the emitter portion 120 and the plurality of front electrode current collectors 142 contacting the emitter portion 120 are formed to complete the front electrode part 140. The front electrode pattern 40a of the front electrode part pattern 40 becomes the plurality of front electrodes 141, and the current collector pattern 40b of the front electrode part pattern 40 becomes the plurality of front electrode current collectors 142.

During the thermal process, the back electrode 151 electrically and physically connected to the substrate 110 is formed. Further, Al contained in the back electrode 151 is distributed (or doped) in the substrate 110 contacting the back electrode 151 to form the back surface field layer 171 between the back electrode 151 and the substrate 110. The back surface field layer 171 is an impurity region doped with impurities (for example, p-type impurities) of the same conductive type as the substrate 110. An impurity doping concentration of the back surface field layer 171 is higher than an impurity doping concentration of the substrate 110, and thus the back surface field layer 171 is a p⁺-type region.

Next, an edge isolation process for removing the emitter portion 120 formed in edges of the substrate 110 is performed using a laser beam to electrically separate the emitter portion 120 on the front surface of the substrate 110 from the emitter portion 120 on the back surface of the substrate 110. Finally, the solar cell 1 shown in FIGS. 1 and 2 is completed.

In embodiments of the invention, the first anti-reflection layer 131 may be a tertiary compound of elements and the second anti-reflection layer 132 may be a binary compound of elements. For example, the first anti-reflection layer 131 may be a silicon oxynitride (SiOxNy) layer. The silicon oxynitride (SiOxNy) layer may include hydrogen (H). The second anti-reflection layer 132 may be a silicon nitride (SiNx) layer. The silicon nitride (SiNx) layer may include H. The tertiary compound of the first anti-reflection layer 131 and the binary compound of the second anti-reflection layer 132 may have two elements common to both layers. In this instance, the two elements that are common to both layers are silicon (Si) and nitrogen (N). The one element that is not common to both layers is oxygen (O), which is present only in the first anti-reflection layer 131.

In an embodiment of the invention, a change in a content of the oxygen at a boundary between the first anti-reflection layer 131 and the second anti-reflection layer 132 need not be abrupt. Rather, at least one of the first anti-reflection layer 131 and the second anti-reflection layer 132 may have a region of varying oxygen content, or a separate layer having a varying oxygen content may be disposed between the first anti-reflection layer 131 and the second anti-reflection layer 132. When the oxygen content is varying, an amount of oxygen thereof may decrease in a direction away from the emitter portion 120.

Next, the efficiency of the solar cell including the anti-reflection layer 130 according to the embodiment of the invention and the efficiency of a solar cell including an anti-reflection layer according to the related art are described below.

The solar cell according to the embodiment of the invention and the solar cell according to the related art each used a substrate that was formed of p-type single crystal silicon and had a thickness of about 200 μm and the size of 156 nm×156 nm. The substrate used was textured to have a textured surface. An n⁺-type emitter portion having a resistance of about 50 Ω/sheet was formed using a thermal distribution method. A first anti-reflection layer of an anti-reflection layer used in first to third examples according to the embodiment of the invention was formed on the emitter portion using silicon oxynitride (SiOxNy) and had a refractive index of about 1.6. A second anti-reflection layer of the anti-reflection layer used in the first to third examples was formed on the first anti-reflection layer using silicon nitride (SiNx) and had a refractive index of about 2.1 and a thickness of about 92 nm. In the first to third examples, a thickness of the first anti-reflection layer used in the first example was about 10 nm, a thickness of the first anti-reflection layer used in the second example was about 20 nm, and a thickness of the first anti-reflection layer used in the third example was about 30 nm.

On the other hand, an anti-reflection layer used in a comparative example according to the related art had a single-layered structure formed using silicon nitride (SiNx) and had a refractive index of about 2.1 and a thickness of about 92 nm.

A front electrode part connected to the emitter portion and a back electrode connected to the substrate were formed using a screen printing method. The front electrode part contained silver (Ag), and the back electrode contained aluminum (Al).

Configurations of the solar cells used in the first to third examples according to the embodiment of the invention were substantially the same as configuration of the solar cell used in the comparative example according to the related art, except the anti-reflection layer.

The following Table 1 indicates a short-circuit current density Jsc, an open-circuit voltage Voc, a fill factor FF, and a photoelectric transformation efficiency EF of each of the solar cells according to the first to third examples and the comparative example. The short-circuit current density Jsc is a current per a unit area calculated when a voltage value on a current-voltage curve of the solar cell is zero. The open-circuit voltage Voc is a voltage obtained when a current value on the current-voltage curve of the solar cell is zero. The fill factor FF is a percentage of a multiplication of a maximum output voltage and a maximum output current based on a multiplication of the open-circuit voltage and a short-circuit current.

TABLE 1

| | Jsc (mA/cm²) | Voc (V) | FF (%) | EF (%) |
|---|---|---|---|---|
| Comparative | 34.25 | 0.621 | 77.84 | 16.56 |
| example | | | | |
| First | 34.344 | 0.626 | 78.65 | 16.9 |
| example | | | | |
| Second | 34.316 | 0.625 | 78.89 | 16.92 |
| example | | | | |
| Third | 33.956 | 0.624 | 79.01 | 16.73 |
| example | | | | |

As indicated in the above Table 1, the short-circuit current density Jsc, the open-circuit voltage Voc, and the fill factor FF of the solar cells according to the first to third examples each including the anti-reflection layer having a double-layered structure were more excellent (or better) than those of the solar cell according to the comparative example including the anti-reflection layer having the single-layered structure. Hence, the photoelectric transformation efficiency EF of the solar cells according to the first to third examples was more excellent (or better) than that of the solar cell according to the comparative example. It could be seen from the above Table 1 that the efficiency of the solar cells according to the first to third examples increased by about 0.3%, compared with the solar cell according to the comparative example.

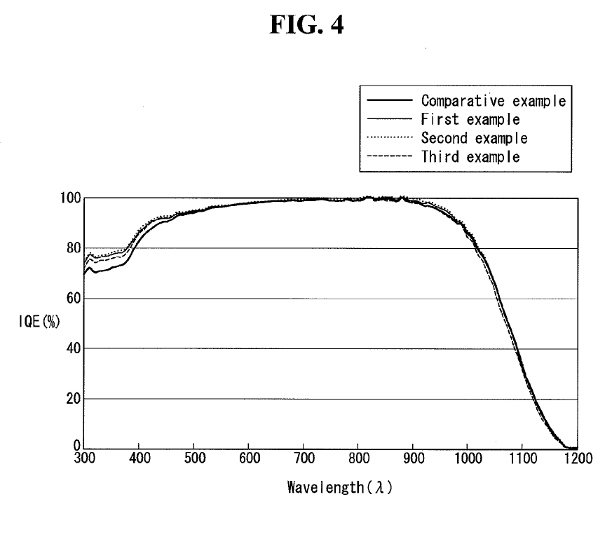

FIG. 4 is a graph illustrating a relationship between a wavelength of light and an internal quantum efficiency (IQE) value (unit: %) in the solar cells according to the first to third examples and the comparative example.

In general, as unstable bonds increase around an incident surface of the substrate 110, a trap amount of carriers increases because of the unstable bonds. Hence, the passivation effect decreases. Further, as the passivation effect decreases, the IQE value decreases. As indicated in the graph shown in FIG. 4, the IQE value in the first to third examples was greater than the IQE value in the comparative example in a short wavelength band having a wavelength of about 300 nm to 600 nm. In other words, in the first to third examples, the trap amount of carriers further decreased because of the passivation effect resulting from the silicon oxynitride (SiOxNy) layer corresponding to the lower layer, compared with the comparative example.

Accordingly, in the anti-reflection layer having the double-layered structure according to the first to third examples, even if a thickness of the lower layer (i.e., the silicon oxynitride (SiOxNy) layer) greatly decreased to about 5 nm to 35 nm, the efficiency of the solar cells according to the first to third examples was more excellent (or better) than the efficiency of the comparative example.

Accordingly, in the solar cell according to the example embodiment of the invention, the process time and the manufacturing cost of the anti-reflection layer are reduced without a reduction in the efficiency of the solar cell. As a result, the process time and the manufacturing cost of the solar cell according to the example embodiment of the invention are reduced.

Although embodiments have been described with reference to a number of illustrative embodiments thereof, it should be understood that numerous other modifications and embodiments can be devised by those skilled in the art that will fall within the scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A solar cell, comprising:
a substrate of a first conductive type;
an emitter portion of a second conductive type opposite the first conductive type, the emitter portion forming a p-n junction along with the substrate;
a first anti-reflection layer positioned on the emitter portion, the first anti-reflection layer having a thickness of about 5 nm to 35 nm;
a second anti-reflection layer positioned on the first anti-reflection layer;
a first electrode electrically connected to the emitter portion; and
a second electrode electrically connected to the substrate.

2. The solar cell of claim 1, wherein the first anti-reflection layer is formed of silicon oxynitride.

3. The solar cell of claim 2, wherein the first anti-reflection layer has a refractive index of about 1.5 to 3.4.

4. The solar cell of claim 1, wherein the second anti-reflection layer is formed of silicon nitride.

5. The solar cell of claim 4, wherein the second anti-reflection layer has a thickness of about 50 nm to 100 nm.

6. The solar cell of claim 5, wherein the second anti-reflection layer has a refractive index of about 1.45 to 2.4.

7. The solar cell of claim 1, further comprising a back surface field layer positioned between the substrate and the second electrode.

8. A method for manufacturing a solar cell comprising:
forming an emitter portion of a second conductive type opposite a first conductive type at a substrate of the first conductive type;
forming a first anti-reflection layer on the emitter portion to a thickness of about 5 nm to 35 nm;
forming a second anti-reflection layer on the first anti-reflection layer; and
forming a first electrode electrically connected to the emitter portion and a second electrode electrically connected to the substrate.

9. The method of claim 8, wherein the forming of the first anti-reflection layer includes forming the first anti-reflection layer using silicon oxynitride.

10. The method of claim 9, wherein the first anti-reflection layer has a refractive index of about 1.5 to 3.4.

11. The method of claim 8, wherein the forming of the second anti-reflection layer includes forming the second anti-reflection layer using silicon nitride.

12. The method of claim 11, wherein the second anti-reflection layer has a thickness of about 50 nm to 100 nm.

13. The method of claim 12, wherein the second anti-reflection layer has a refractive index of about 1.45 to 2.4.

14. The method of claim 8, wherein the forming of the first and second electrodes includes:
printing a first paste on the second anti-reflection layer to form a first electrode pattern;
printing a second paste on the substrate to form a second electrode pattern; and
performing a thermal process on the substrate having the first electrode pattern and second electrode pattern to respectively form the first electrode electrically connected to the emitter portion and the second electrode electrically connected to the substrate.

15. The method of claim 14, wherein the forming of the first and second electrodes further includes forming a back surface field layer between the substrate and the second electrode when the thermal process is performed on the substrate.
